(19) United States
(12) Patent Application Publication
(10) Pub. No.: US 2023/0065768 A1
(43) Pub. Date: Mar. 2, 2023

(54) METHOD FOR FABRICATING TERAHERTZ DEVICE

(71) Applicant: ELECTRONICS AND TELECOMMUNICATIONS RESEARCH INSTITUTE, Daejeon (KR)

(72) Inventors: Dong Woo PARK, Daejeon (KR); Kyung Hyun PARK, Daejeon (KR); Dong-Young KIM, Daejeon (KR); Mugeon KIM, Daejeon (KR); Jun-Hwan SHIN, Daejeon (KR); Eui Su LEE, Daejeon (KR); IL MIN LEE, Daejeon (KR); Da Hye CHOI, Daejeon (KR)

(73) Assignee: ELECTRONICS AND TELECOMMUNICATIONS RESEARCH INSTITUTE, Daejeon (KR)

(21) Appl. No.: 17/507,796

(22) Filed: Oct. 21, 2021

(30) Foreign Application Priority Data
Aug. 25, 2021 (KR) 10-2021-0112023

(51) Int. Cl. H01L 31/02; H01L 23/66; H01L 31/0232; H01L 31/0304; H01L 31/09; H01L 31/18

(52) U.S. Cl. CPC H01L 31/02002; H01L 23/66; H01L 31/02327; H01L 31/0304; H01L 31/09; H01L 31/1892; H01L 2223/6677

(57) ABSTRACT

Disclosed is a method for fabricating a terahertz device, the method including providing a substrate, doping a conductive impurity on an upper surface of the substrate to form an electrode layer, patterning the electrode layer to form antenna electrodes, and forming a photomixer between the antenna electrodes.

### CROSS-REFERENCE TO RELATED APPLICATIONS

This U.S. non-provisional patent application claims priority under 35 U.S.C. § 119 of Korean Patent Application No. 10-2021-0112023, filed on Aug. 25, 2021, the entire contents of which are hereby incorporated by reference.

### BACKGROUND

The present disclosure herein relates to a method for fabricating an electronic device, and more particularly, to a method for fabricating a terahertz device.

As a growth apparatus and a growth technique of molecular beam epitaxy (MBE) and metal organic chemical vapor deposition (MOCVD) are rapidly developed from the 1980s, the III-V compound semiconductor makes a great contribution on development of the semiconductor physics, the optical communication, and electronic devices by developing the growth technique and realizing a low dimensional (2D/1D/0D) structure. The III-V compound semiconductor is widely used as an activation layer of a high performance electronic device such as a terahertz device because of a direct transition band gap and high charge mobility thereof. In recent years, the III-V compound semiconductor may be mounted onto a silicon substrate having excellent compatibility and realized as a large-area device.

### SUMMARY

The present disclosure provides a method for fabricating a terahertz device capable of preventing a bonding damage caused by a solder bump and increasing productivity.

An embodiment of the inventive concept provides a method for fabricating a terahertz device, the method including: providing a substrate; doping a conductive impurity on an upper surface of the substrate to form an electrode layer; patterning the electrode layer to form antenna electrodes; and bonding a photomixer onto the antenna electrodes.

In an example, the substrate may include silicon, and the photomixer may include a group III-V semiconductor.

In an example, the conductive impurity may include boron (B), aluminum (Al), gallium (Ga), indium (In), phosphorus (P), arsenic (As), or antimony (Sb).

In an example, the photomixer may be formed on an etch stop layer and a dummy substrate, and the method may further include removing the etch stop layer and the dummy substrate.

In an example, the etch stop layer may include a dielectric material or an adhesive, and the dummy substrate may include quartz, gallium arsenide (GaAs), or gallium nitride (GaN).

In an example, the method may further include forming internal electrodes and interlayer insulation layers on the substrate.

In an example, the internal electrodes may include: a lower electrode; and an upper electrode disposed above the lower electrode.

In an example, the interlayer insulation layers may include: a lower interlayer insulation layer disposed between the lower electrode and the upper electrode; and an upper interlayer insulation layer disposed between the upper electrode and the antenna electrodes.

In an example, the forming of the antenna electrodes may include forming the antenna electrodes and island electrodes between the antenna electrodes, and the island electrodes may be disposed between the upper interlayer insulation layer and the photomixer.

In an example, the method may further include: forming a dielectric layer at the outside of the internal electrodes and the interlayer insulation layers on the substrate; and forming a contact plug connected to the internal electrodes and the antenna electrodes in the dielectric layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a flowchart representing an example of a method for fabricating a terahertz device according to an embodiment of the inventive concept;

FIGS. 2A to 2E are process cross-sectional views of the terahertz device according to an embodiment of the inventive concept;

FIG. 3 is a view illustrating antenna electrodes formed from an electrode layer of FIG. 2B;

FIG. 4 is a view illustrating an etch stop layer and a dummy substrate on a photomixer of FIG. 2D;

FIG. 5 is a cross-sectional view illustrating an example of the terahertz device according to an embodiment of the inventive concept;

FIG. 6 is a perspective view illustrating another example of the terahertz device according to an embodiment of the inventive concept;

FIG. 7 is a plan view illustrating another example of the terahertz device according to an embodiment of the inventive concept;

FIG. 8 is a flowchart representing an example of the method for fabricating the terahertz device according to an embodiment of the inventive concept; and

FIGS. 9 to 14 are process cross-sectional views of the terahertz device according to an embodiment of the inventive concept.

### DETAILED DESCRIPTION

Hereinafter, exemplary embodiments of the present invention will be described in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present disclosure is only defined by scopes of claims. Like reference numerals refer to like elements throughout.

In the specification, the technical terms are used only for explaining a specific exemplary embodiment while not limiting the present invention. The terms of a singular form may include plural forms unless referred to the contrary. The meaning of ‘comprises’ and/or ‘comprising’ specifies a component, a step, an operation and/or an element does not exclude other components, steps, operations and/or elements. Also, it will be understood that terms used in this specification such as a terahertz device, an impurity, doping, and an antenna have a meaning generally used in the electric or semiconductor field. Since preferred embodiments are provided below, the order of the reference numerals given in the description is not limited thereto.

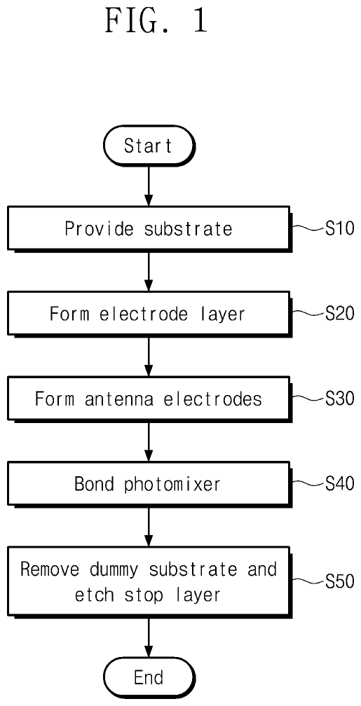

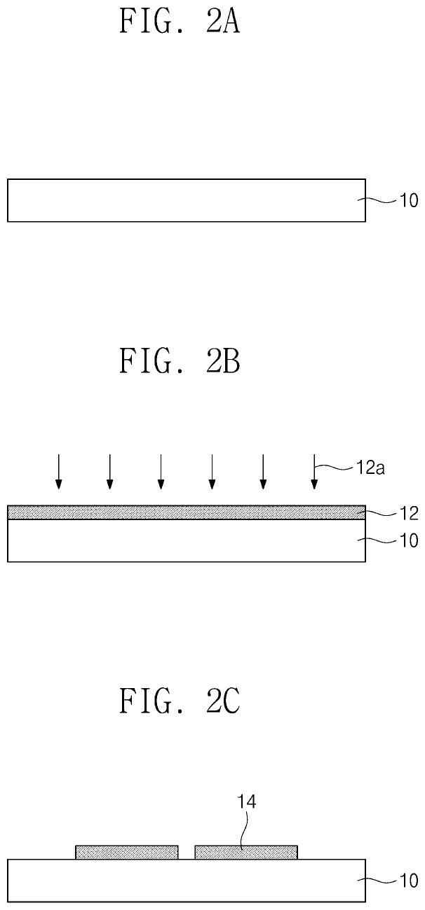

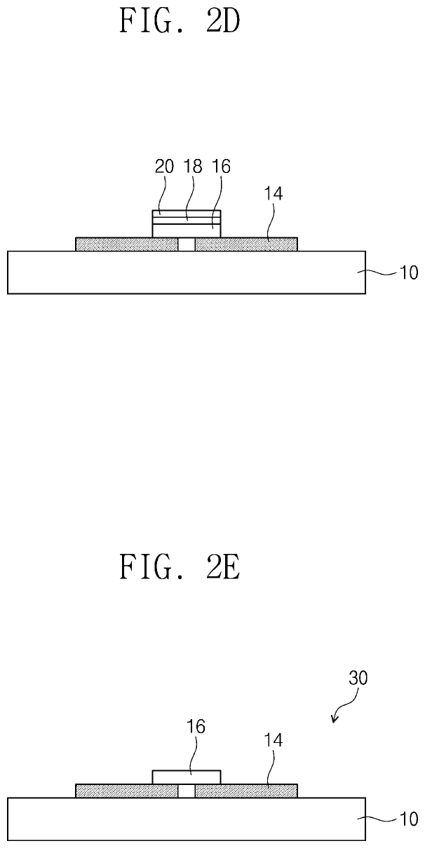

FIG. 1 is a flowchart representing an example of a method for fabricating a terahertz device according to an embodiment of the inventive concept. FIGS. 2A to 2E are process cross-sectional views of the terahertz device according to an embodiment of the inventive concept.

Referring to FIGS. 1 and 2, a substrate 10 is provided in a process S10. For example, the substrate 10 may be a silicon substrate. Alternatively, the substrate 10 may be a silicon on insulator (SOI) substrate. However, the embodiment of the inventive concept is not limited thereto. For example, the process S10 of providing the substrate 10 may be a process of preparing the substrate 10. A driving device such as a transistor or an optical waveguide (not shown) may be formed on the substrate 10.

Referring to FIGS. 1 and 2B, an upper surface of the substrate 10 is doped with a conductive impurity 12a to form an electrode layer 12 in a process S20. For example, the conductive impurity 12a may include a p-type impurity or an n-type impurity. The p-type impurity may include boron (B), aluminum (Al), gallium (Ga), or indium (In). The n-type impurity may include phosphorus (P), arsenic (As), or antimony (Sb). The conductive impurity 12a may be doped in the substrate 10 by an ion implantation method. The conductive impurity 12a may have a doping concentration of about 1×10²¹ EA/cm³ or more. The electrode layer 12 may have a specific resistance of about 100 μΩcm or less and a transmittance of about 11.8 or less. The electrode layer 12 may have a thickness and/or a depth of about 1 μm or less from the top surface of the substrate 10. For example, the electrode layer 12 may have a thickness of about 200 nm, about 370 nm, or about 530 nm. However, the embodiment of the inventive concept is not limited thereto. Although not shown, the electrode layer 12 may include a plurality of layers having different doping concentrations of the conductive impurity 12a.

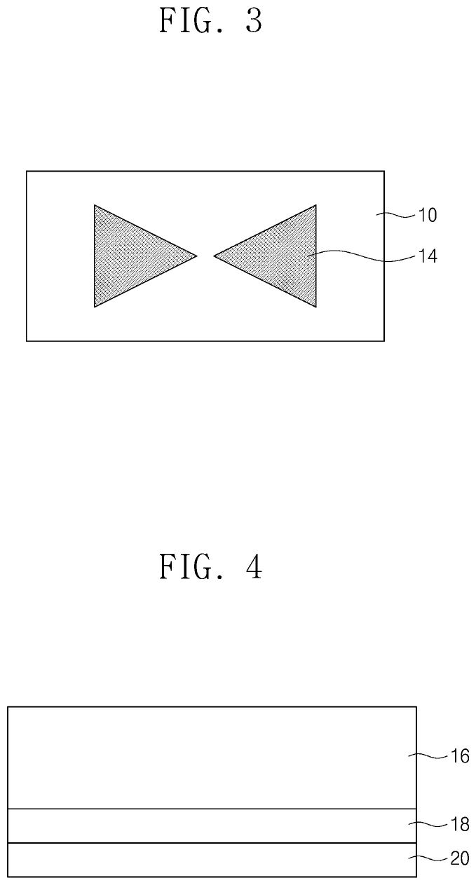

FIG. 3 is a view illustrating antenna electrodes 14 formed from the electrode layer 12 of FIG. 2B.

Referring to FIGS. 1, 2C, and 3, the electrode layer 12 is patterned to form antenna electrodes 14 in a process S30. The patterning process of the electrode layer 12 may include a photolithography process and an etching process. For example, the antenna electrodes 14 may have a bow-tie type or a horn type. For example, each of the antenna electrodes 14 may have a triangular shape. The antenna electrodes 14 may be adjacent to each other. Although not shown, the antenna electrodes 14 may have a stair shape. However, the embodiment of the inventive concept is not limited thereto.

FIG. 4 is a view illustrating an etch stop layer 18 and a dummy substrate 20 on a photomixer 16 of FIG. 2D.

Referring to FIGS. 1, 2D, and 4, the photomixer 16 is bonded on the antenna electrodes 14 in a process S40. The photomixer 16 may be bonded to the antenna electrodes 14 through a transferring process. For example, the photomixer 16 may be transferred onto the antenna electrodes 14 by the dummy substrate 20 and the etch stop layer 18.

Firstly, the photomixer 16 may be formed on the dummy substrate 20 and the etch stop layer 18 before bonded. The dummy substrate 20 may include a substrate made of quartz, gallium arsenide (GaAs), or gallium nitride (GaN). The etch stop layer 18 may include a dielectric material and/or an adhesive. The photomixer 16 may include III-V semiconductor. The photomixer 16 may be thinned through a lapping process. Each of the photomixer 16, the etch stop layer 18, and the dummy substrate 20 may be fabricated to have a predetermined shape and length through a scribing process and/or a braking process.

Thereafter, the photomixer 16 may be bonded to the antenna electrodes 14 by the van der Waals force. The van der Waals force between the photomixer 16 and the antenna electrodes 14 may prevent a bonding damage caused by a typical solder bump. Also, the van der Waals force may directly bond and/or couple the photomixer 16 and the antenna electrodes 14 to improve productivity.

Referring to FIGS. 1 and 2E, the etch stop layer 18 and the dummy substrate 20 on the photomixer 16 are removed in a process S50. The etch stop layer 18 and the dummy substrate 20 may be separated from the substrate 20 by a wet etching solution and/or an organic solvent. The wet etching solution may etch the etch stop layer 18 and the dummy substrate 20. When the etch stop layer 18 is an adhesive, the organic solvent may dissolve the etch stop layer 18 to separate the photomixer 16 from the dummy substrate 20. The photomixer 16 may be exposed.

The photomixer 16 and the antenna electrodes 14 may function as a terahertz device 30. That is, the terahertz device 30 may include the antenna electrodes 14 and the photomixer 16. The photomixer 16 may process a terahertz wave. The antenna electrodes 14 may transmit or receive the terahertz wave in a wireless manner. The terahertz wave may have a transmitting and receiving frequency determined based on a thickness of the antenna electrodes 14. When each of the antenna electrodes 14 has a thickness of about 200 nm, the photomixer 16 may transceive the terahertz wave of about 1000 GHz. When each of the antenna electrodes 14 has a thickness of about 370 nm, the photomixer 16 may transceive the terahertz wave of about 300 GHz. When each of the antenna electrodes 14 has a thickness of about 530 nm, the photomixer 16 may transceive the terahertz wave of about 150 GHz.

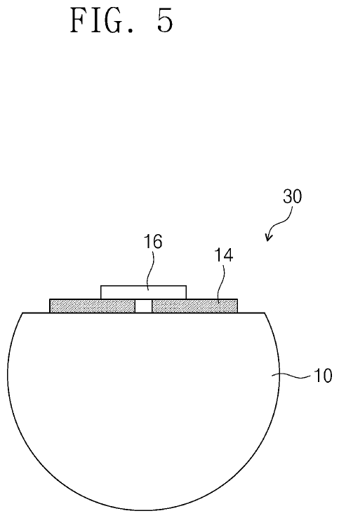

FIG. 5 is a view illustrating one example of the terahertz device 30 according to an embodiment of the inventive concept.

Referring to FIG. 5, the substrate 10 of the terahertz device 30 according to an embodiment of the inventive concept may include a silicon lens. A lower surface of the substrate 10 may have a hemi-sphere shape. The terahertz wave may be received by the antenna electrodes 14 and the photomixer 16 through the substrate 10. The substrate 10 may focus the terahertz wave to the antenna electrodes 14 and the photomixer 16. Alternatively, the terahertz wave may be received by the antenna electrodes 14 and the photomixer 16 and emitted and/or radiated through the substrate 10. However, the embodiment of the inventive concept is not limited thereto.

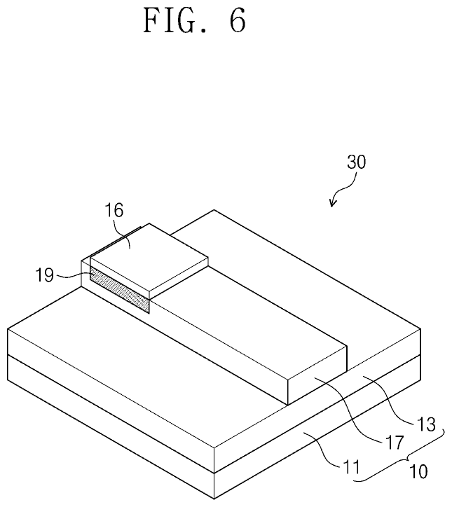

FIG. 6 is a view illustrating another example of the terahertz device 30 according to an embodiment of the inventive concept.

Referring to FIG. 6, the substrate 10 of the terahertz device 30 according to an embodiment of the inventive concept may be the SOI substrate. The substrate 10 may include a lower substrate 11, an insulation layer 13, and an optical waveguide 17. The lower substrate 11 may be a silicon substrate. The insulation layer 13 may be disposed on the lower substrate 11. The insulation layer 13 may include a silicon oxide (SiO₂). The optical waveguide 17 may be disposed on the insulation layer 13. The optical waveguide 17 may include crystalline silicon, polycrystalline silicon, or amorphous silicon. For example, the optical waveguide 17 may include a ridge waveguide. Alternatively, the optical waveguide 17 may include a rib waveguide. However, the embodiment of the inventive concept is not limited thereto. The optical waveguide 17 may have an impurity bonding layer 19. The impurity bonding layer 19 may include a p-type impurity or an n-type impurity. The photomixer 16 may be bonded to the impurity bonding layer 19.

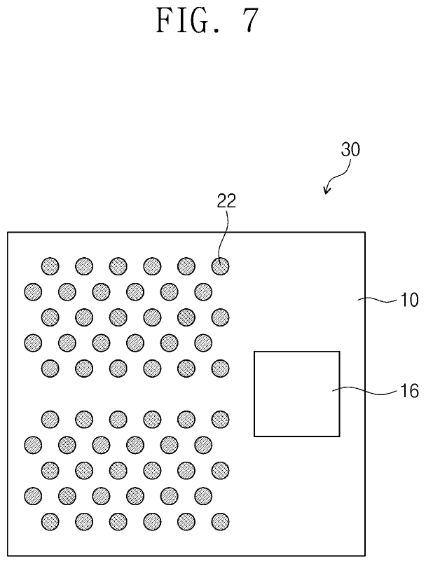

FIG. 7 is a view illustrating another example of the terahertz device 30 according to an embodiment of the inventive concept.

Referring to FIG. 7, the terahertz device 30 according to an embodiment of the inventive concept may include a substrate 10, a photomixer 16, and posts 22. The substrate 100 may include a photonics crystal. Additionally, the substrate 10 may include a quantum well layer below the photonics crystal. However, the embodiment of the inventive concept is not limited thereto. The photomixer 16 may be disposed on one side of the substrate 10. Although not shown, the photomixer 16 may be bonded onto the substrate 10 by an impurity layer or an impurity bonding layer. The posts 22 may be disposed on the other side of the substrate 10. The posts 22 may transceive the terahertz wave in a wireless manner.

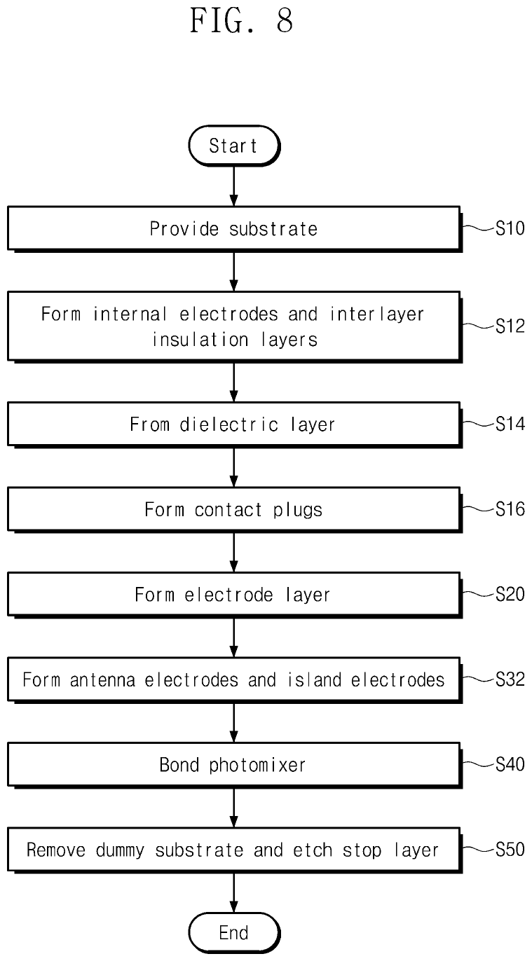

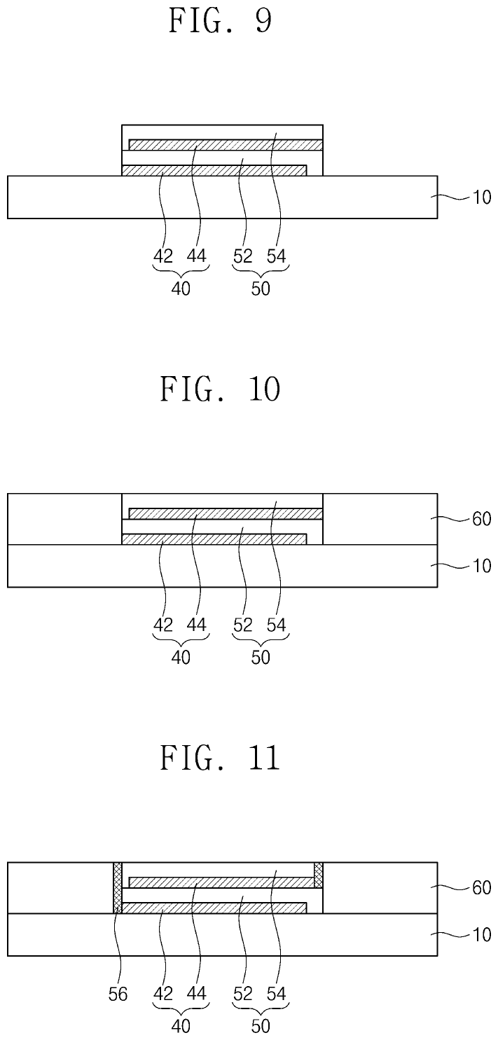

FIG. 8 is a flowchart representing an example of the method for fabricating the terahertz device according to an embodiment of the inventive concept. FIGS. 9 to 14 are process cross-sectional views of the terahertz device according to an embodiment of the inventive concept.

Referring to FIGS. 2A and 8, the substrate 10 is provided in a process S10.

Referring to FIGS. 8 and 9, internal electrodes 40 and interlayer insulation layers 50 are formed in a process S12. The internal electrodes 40 and the interlayer insulation layers 50 may be alternately laminated. The internal electrodes 40 may reduce a three-dimensional spaced distance between the antenna electrodes 14 to increase a production efficiency of the terahertz wave although not shown in FIGS. 8 and 9. For example, the internal electrodes 40 may include metal such as gold (Au), aluminum (Al), copper (Cu), tungsten (W), titanium (Ti), or tantalum (Ta). For example, the internal electrodes 40 may include a lower electrode 42 and an upper electrode 44. The lower electrode 42 may be disposed between the substrate 10 and the upper electrode 44. The upper electrode 44 may be formed on the lower electrode 42. The interlayer insulation layers 50 may include a silicon oxide or a silicon nitride. For example, the interlayer insulation layers 50 may include a lower interlayer insulation layer 52 and an upper interlayer insulation layer 54. The lower interlayer insulation layer 52 may be formed between the lower electrode 42 and the upper electrode 44. The upper interlayer insulation layer 54 may be formed on the upper electrode 44.

Referring to FIGS. 8 and 10, a dielectric layer 60 may be formed at the outside of the internal electrodes 40 and the interlayer insulation layers 50 in a process S14. The dielectric layer 60 may include a silicon oxide. The dielectric layer 60 may be formed on the substrate 10 and the upper interlayer insulation layer 54 by a chemical vapor deposition method. Thereafter, the dielectric layer 60 may be flattened by a chemical mechanical polishing (CMP) method. The dielectric layer 60 may selectively expose the upper interlayer insulation layer 54.

Referring to FIGS. 8 and 11, contact plugs 56 are formed in the dielectric layer 60 in a process S16. The contact plugs 56 may be individually connected to the lower electrode 42 and the upper electrode 44. A portion of the contact plugs 56 may be exposed from the dielectric layer 60 and the upper interlayer insulation layer 54. The contact plugs 56 may include the same metal as that of each of the lower electrode 42 and the upper electrode 44.

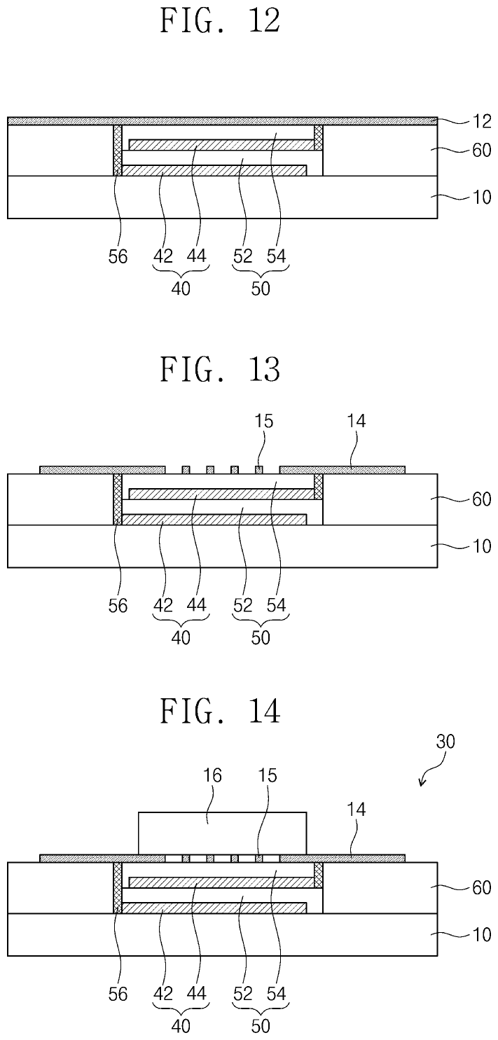

Referring to FIGS. 8 and 12, the electrode layer 12 is formed on the upper interlayer insulation layer 54, the dielectric layer 60, and the contact plugs 56. The electrode layer 12 may include epitaxial silicon, crystalline silicon, polycrystalline silicon, and amorphous silicon formed by a chemical vapor deposition method (e.g., MOCVD) or a physical vapor deposition method (e.g., MBE). The electrode layer 12 may be doped by the conductive impurity 12a (refer to FIG. 2B). Also, the electrode layer 12 may include a group III-V semiconductor such as GaAs or GaN. However, the embodiment of the inventive concept is not limited thereto.

Referring to FIGS. 8 and 13, antenna electrodes 14 and island electrodes 15 are formed by patterning the electrode layer 12 in a process S32. The patterning process of the electrode layer 12 may include a photolithography process and an etching process. For example, the antenna electrodes 14 may have a bow-tie type or a horn type. The antenna electrodes 14 may be connected to the contact plugs 56, respectively. The antenna electrodes 14 may be connected to the lower electrode 42 and the upper electrode 44. The island electrodes 15 may be formed between the antenna electrodes 14. The island electrodes 15 may be spaced a uniform distance from each other. Alternatively, the island electrodes 15 may be formed adjacent to the antenna electrodes 14.

Referring to FIGS. 8 and 14, the photomixer 16 is bonded onto the antenna electrodes 14 and the island electrodes 15 in a process S40, and the dummy substrate 20 and the etch stop layer 18 on the photomixer 16 are removed in a process S50.

The photomixer 16 may be bonded to the antenna electrodes 14 and the island electrodes 15 by the van der Waals force. The island electrodes 15 may contact the photomixer 16 to increase an adhesive force and/or a bonding force of the photomixer 16. Also, the island electrodes 15 may reduce an electrically spaced distance between the island electrodes 15 and the antenna electrodes 14 to increase a transmission and/or reception efficiency of the terahertz wave, although not shown in FIGS. 8 and 14. The island electrodes 15 may increase an electric field and/or a current between the antenna electrodes 14 through a surface plasmon effect of the terahertz wave. The island electrodes 15 may function as a channel between the antenna electrodes 14. That is, the island electrodes 15 may increase the electric field and/or the current between the antenna electrodes 14 through a collective surface plasmon effect thereof. The terahertz wave may be received by and/or transmitted to the antenna electrodes 14 by transmitting through the substrate 10 or the photomixer 16.

As described above, the method for fabricating the terahertz device according to the embodiment of the inventive concept may bond the photomixer onto the antenna electrode including the silicon having the conductive impurity by the van der Waals force to prevent the bonding damage caused by the typical solder bump and increase the productivity.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A method for fabricating a terahertz device, comprising:
providing a substrate;
doping a conductive impurity on an upper surface of the substrate to form an electrode layer;
patterning the electrode layer to form antenna electrodes; and
bonding a photomixer onto the antenna electrodes.

2. The method of claim 1, wherein the substrate comprises silicon, and
the photomixer comprises III-V semiconductor.

3. The method of claim 1, wherein the conductive impurity comprises boron (B), aluminum (Al), gallium (Ga), indium (In), phosphorus (P), arsenic (As), or antimony (Sb).

4. The method of claim 1, wherein the photomixer is formed on an etch stop layer and a dummy substrate, and
the method further comprises removing the etch stop layer and the dummy substrate.

5. The method of claim 4, wherein the etch stop layer comprises a dielectric material or an adhesive, and
the dummy substrate comprises quartz, gallium arsenide (GaAs), or gallium nitride (GaN).

6. The method of claim 1, further comprising forming internal electrodes and interlayer insulation layers on the substrate.

7. The method of claim 6, wherein the internal electrodes comprise:
a lower electrode; and
an upper electrode disposed above the lower electrode.

8. The method of claim 7, wherein the interlayer insulation layers comprise:
a lower interlayer insulation layer disposed between the lower electrode and the upper electrode; and
an upper interlayer insulation layer disposed between the upper electrode and the antenna electrodes.

9. The method of claim 8, wherein the forming of the antenna electrodes comprises forming the antenna electrodes and island electrodes between the antenna electrodes,
wherein the island electrodes are disposed between the upper interlayer insulation layer and the photomixer.

10. The method of claim 6, further comprising:
forming a dielectric layer at the outside of the internal electrodes and the interlayer insulation layers on the substrate; and
forming a contact plug connected to the internal electrodes and the antenna electrodes in the dielectric layer.
